(19) United States
(12) Patent Application Publication
(10) Pub. No.: US 2002/0039818 A1
(43) Pub. Date: Apr. 4, 2002

(54) Wavy-shaped deep trench and method of forming

(76) Inventor: Szetsen Steven Lee, Taipei City (TW)

Correspondence Address: FRANK R. OCCHIUTI, Fish & Richardson P.C., 225 Franklin Street, Boston, MA, 02110-2804, US

(21) Appl. No.: 09/864,801

(22) Filed: May 24, 2001

Related U.S. Application Data
(63) Continuation-in-part of application No. 09/490,459, filed on Jan. 25, 2000, now abandoned.

(51) Int. Cl. H01L 21/8238; H01L 27/108; H01L 29/76; H01L 29/94; H01L 31/119

(52) U.S. Cl. 438/221

(57) ABSTRACT

The present invention provides a method for forming a wavy-shaped deep trench in a substrate. The method comprises the following steps. First, the method forms a shielding layer with an aperture in the substrate. Second, the method performs a first etch step, creating a first sidewall with positive slope under the aperture. Third, the method performs a second etch step, creating a second sidewall with negative slope under the aperture. The method sequentially and periodically alternates the first etch step and the second etch step to remove a predetermined depth of the substrate and form a wavy-shaped deep trench. A benefit of the present invention is that a deep trench with a wavy sidewall can be formed by a single plasma operation.

This application is a continuation-in-part of U.S. application Ser. No. 09/490,459, filed Jan. 25, 2000, now pending.

### BACKGROUND OF THE INVENTION

1. Field of the Invention

The present invention generally relates to a method for forming a deep trench. More specifically, the present invention relates to a method for forming a wavy-shaped deep trench using a single plasma operation.

2. Description of the Related Art

Deep trenches (DTs) are generally applied in the structure of dynamic random access memory (DRAM) cells and micro electro-mechanic structures (MEMS).

When a DT is applied to the structure of DRAM, the purpose of the DT is to provide a capacitor for storing charges and memorizing data. FIG. 1 is a DT diagram used in DRAM according to the prior art. A DT 10 is constructed by removing part of a substrate 12. While building the capacitor in the DRAM, a dielectric layer (not shown) is formed on the surface of the DT 10 and a conductive material (not shown) fills in the DT 10. The top electrode plate and the bottom electrode plate are the conductive material and the substrate 12, respectively. The greater the capacitance of the capacitor, the less the influence on the data of leakage due to the environment. Thus, the time between two fresh pulses can be extended to save power consumption. Much effort has been devoted to increasing the surface of the DT for increasing capacitance. One method for increasing the surface area of the DT is to build a “deeper” deep trench. However, a higher aspect ratio, defined as the width of the trench divided by the depth of the trench, leads to a higher occurrence of etch stop during substrate etching when forming the DT. It also makes filling in the conductive material during the subsequent processes more difficult. Another method for increasing the surface area of the DT is to build a bottle-shaped DT, as shown in FIG. 2. However, the capacitance increased by this method is not high. Furthermore, a lot of steps must be added to the process flow to achieve the bottle-shaped DT. Thus, the bottle-shaped DT is costly.

DTs can also be applied in MEMS. Please refer to FIG. 3. FIG. 3 is a cross-sectional diagram of a shock/vibration detector in MEMS. A shock/vibration detector has a DT 14 and a rod 16 positioned in the center of the DT 14. Shock or vibration in the environment will cause the rod 16 to swing and contact the sidewall of the DT 14. The action is detected by the current through the contact point where the rod 16 contacts the sidewall of the DT 14. The sensitivity of the shock/vibration detector depends on the amount of play in the rod 16 and the area of its contact with the sidewall. Both can be enhanced by deepening the DT 14. However, this leads to the same problems as mentioned before for DRAM.

### SUMMARY OF THE INVENTION

Therefore, an object of the present invention is to substantially enlarge the capacitance of a capacitor.

A further object of the present invention is to enhance the sensitivity of a shock/vibration detector.

The present invention achieves the indicated purpose by providing a method for forming a wavy-shaped deep trench on a substrate. The method comprises the following steps. First, the method forms a shielding layer with an aperture on the substrate. Second, the method performs a first etch step to cause the substrate to have a first sidewall with positive slope under the aperture. Third, the method performs a second etch step to cause the substrate to have a second sidewall with negative slope under the aperture. The method sequentially and periodically performs the first etch step and the second etch step to remove a predetermined depth of the substrate and form the wavy-shaped deep trench.

The method further comprises a plurality of bye etch steps. Each bye etch step is performed between the first etch step and the second etch step to cause the substrate to have a transitional sidewall under the aperture. The transitional sidewalls connect the first sidewall and the second sidewall and round off the outermost areas of the wavy sidewall.

Differentiation among the first etch step, the second etch step and the bye etch step lies in the alteration of one of the controlling parameters: source power, bias power and oxygen flow-rate. By adjusting at least one of these controlling parameters, the first etch step, the second etch step and the bye etch step can etch sidewalls with different slopes into the substrate to form a wavy sidewall.

The present invention further provides a method for forming a wavy-shaped deep trench on a substrate. The very first step of the method is to form a shielding layer with an aperture on the substrate. Then, an isotropic-dominate etch step is executed to form a concave sidewall under the aperture in the substrate. Then, a passivation film is formed on the concave sidewall to protect it from damage by any subsequent plasma processes. By alternately executing the isotropic-dominate etch step and formation of a passivation film, a predetermined depth of the substrate is removed to form a wavy-shape deep trench.

The present invention substantially enlarges the capacitance of a capacitor and enhances the sensitivity of a shock/vibration detector. Applied in DRAM, the wavy-shaped trench enlarges the surface of the DT to gain higher capacitance. Thus, it is not necessary to achieve higher capacitance through deepening of the deep trench. Further, the first, second and bye etch steps can all be performed with a single etch tool to form the wavy-shaped deep trench according to the present invention, thus saving costs. Applied in MEMS, the wavy-shaped trench enhances possibility for the rod to contact the wavy sidewall, thus the sensitivity of the shock/vibration sensor is improved.

Further features and advantages of the present invention, as well as the structure and operation of various embodiments of the present invention, are described in detail below with respect to the accompanying drawings. In the drawings, like reference numbers indicate identical or functionally similar elements.

### BRIEF DESCRIPTION OF THE DRAWINGS

The following detailed description, given by way of example and not intended to limit the invention solely to the embodiments described herein, will best be understood in conjunction with the accompanying drawings, in which:

FIG. 1 is a DT diagram used in DRAM according to the prior art;

FIG. 2 is a bottle-shaped DT diagram according to the prior art;

FIG. 3 is a cross-sectional diagram of a shock/vibration detector in MEMS;

FIG. 4A is a diagram of a wavy-shaped deep trench applied in DRAM according to the present invention;

FIG. 4B is a diagram of a wavy-shaped deep trench applied in MEMS according to the present invention;

FIG. 4C is an expanded section of FIG. 4A or FIG. 4B;

FIG. 4D is another expanded section of FIG. 4A or FIG. 4B;

FIG. 5 is a cross-sectional view of the aperture before a deep trench is formed thereunder;

FIG. 6 illustrates the dependence of oxygen flow-rate to process time;

FIG. 7 illustrates a trench with a wavy sidewall as well as a trench with a vertical sidewall, corresponding to the oxygen flow-rate in FIG. 6;

FIG. 8A illustrates a cross-section view of a deep trench processed at the time T₁ in FIG. 6; and

FIG. 8B illustrates a cross-section view of a deep trench processed at the time T₂ in FIG. 6.

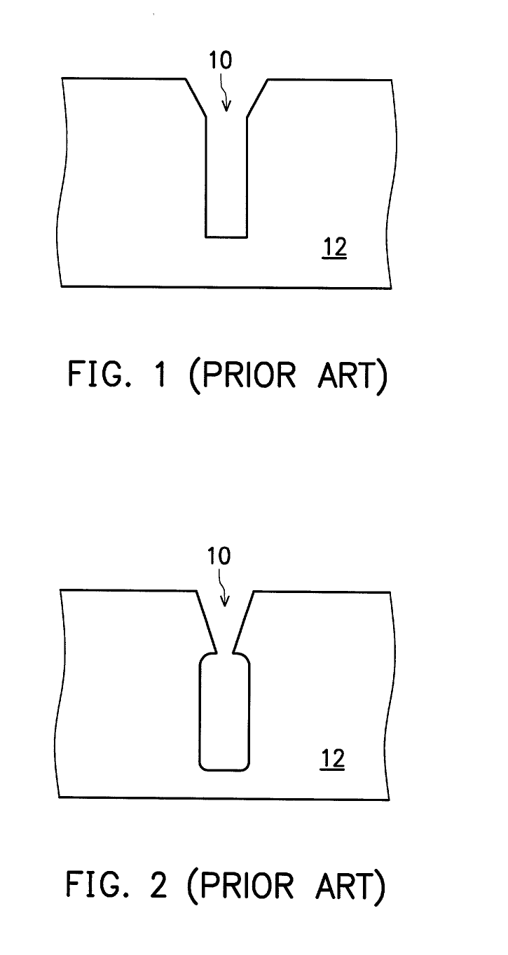

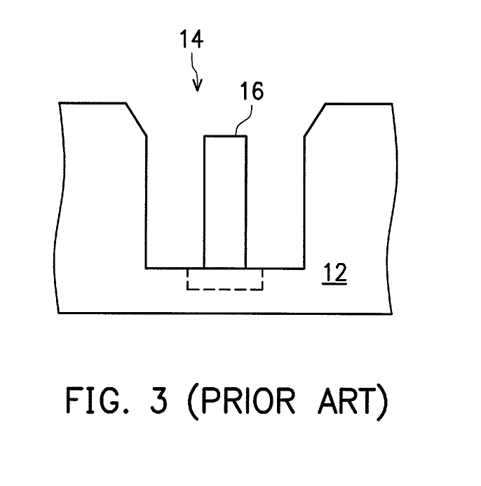

### DETAILED DESCRIPTION OF THE PREFERRED EMBODIMENTS

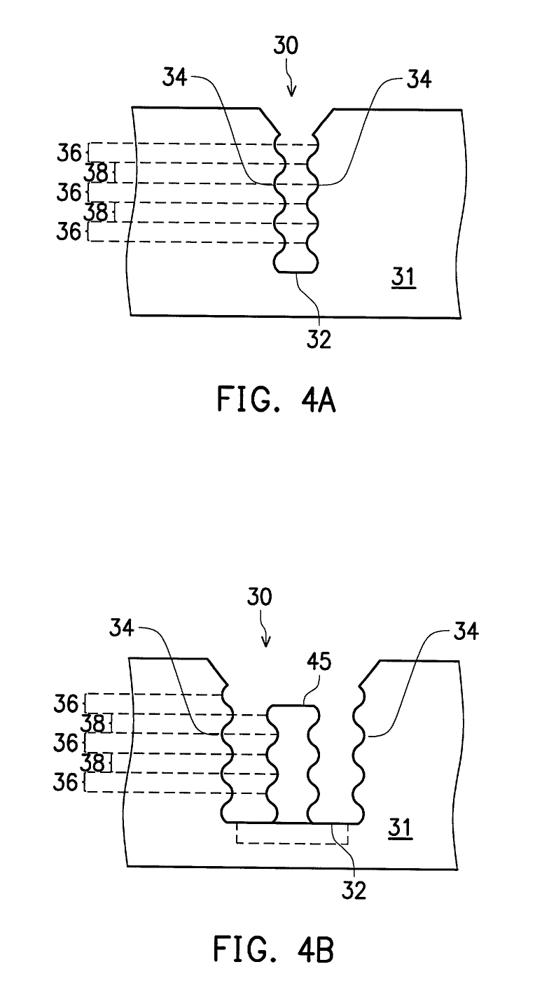

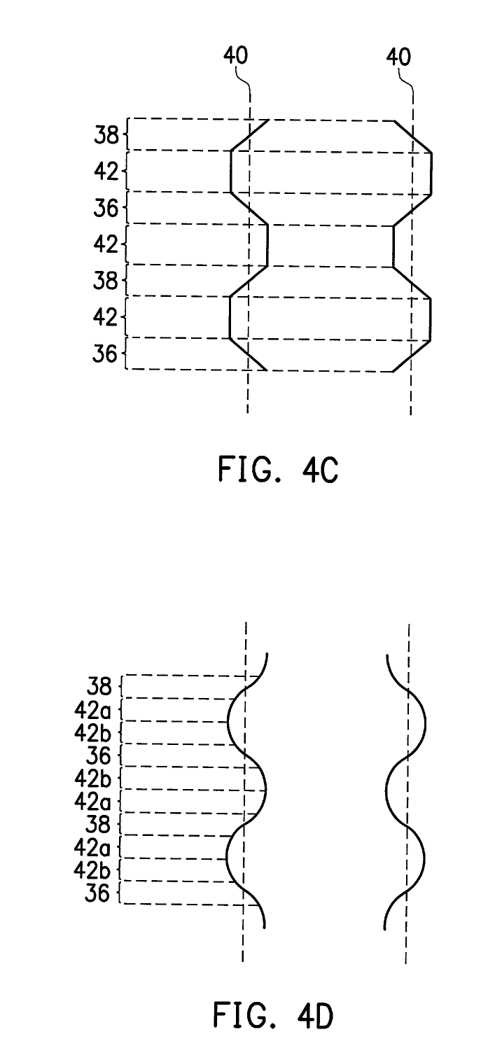

FIG. 4A is a diagram of a wavy-shaped deep trench applied in DRAM according to the present invention. FIG. 4B is a diagram of a wavy-shaped deep trench applied in MEMS according to the present invention. The present invention provides a wavy-shaped deep trench 30 formed by removing part of the substrate 30. The wavy-shaped deep trench 30 has a bottom surface 32 and a wavy sidewall 34 positioned between the bottom surface 32 and the top surface of the substrate 31. The wavy sidewall 34 comprises a plurality of first sidewalls 36 with positive slope and a plurality of second side walls 36 with negative slope. The first and the second sidewalls 34, 36 are interlaced on the wavy sidewall, as shown in FIG. 4A and FIG. 4B.

FIG. 4C is an expanded section of FIG. 4A or FIG. 4B. To round the outermost areas of the wavy sidewall 34, a plurality of transitional sidewalls 42 can be inserted into the wavy sidewall 34. Each transitional sidewall 42 is positioned between a first sidewall 36 and a second sidewall 38. Thus, the shape of the wavy sidewall 34 is not so sharp and the point-discharge effect can be depressed. As shown in FIG. 4C, the dashed line 40 is the vertical line of the top-surface of the substrate 31. It can be seen in FIG. 4C that the transitional sidewalls 42 are perpendicular to the top-surface of the substrate 31.

Obviously, more than a transitional sidewall 42 can be placed between a first sidewall 36 and a second sidewall 38, as shown in FIG. 4D. FIG. 4D is another expanded section of FIG. 4A or FIG. 4B. A first transitional sidewall 42a and a second transitional sidewall 42b are placed between a first sidewall 36 and a second sidewall 38. The purpose of the first and the second transitional sidewalls 42a, 42b is to moderate the slope variation of the wavy sidewall 34 and depress the point discharge effect.

As shown in FIG. 4A, the present invention applied in DRAM enlarges the coupling area since the surface area provided by the wavy sidewall 34 meets the requirements of higher capacitance without deepening the deep trench.

As shown in FIG. 4B, the present invention applied in MEMS improves the sensitivity of a shock/vibration sensor by enhancing the possibility for the rod 45 touching the wavy-side wall 34.

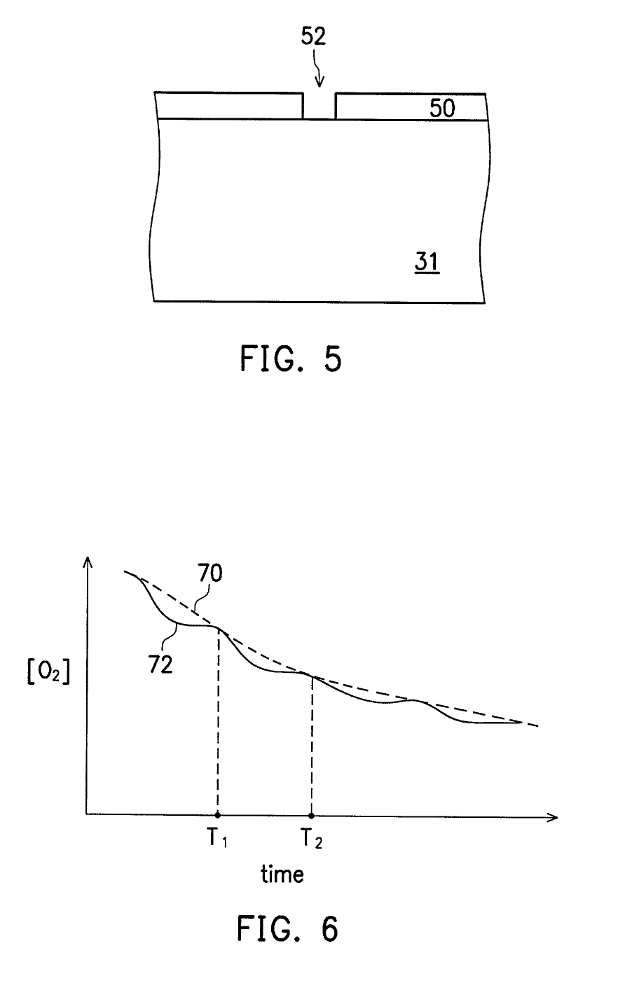

The present invention further provides a method for building the wavy-shaped deep trench as mentioned before. Please refer to FIG. 5. The present invention is applied on a substrate 31, for example, a silicon substrate. First, the present invention forms a shielding layer 50 with an aperture 52 on the substrate 31. For example, the shielding layer 50 is photoresist or silicon-oxide as a mask for the subsequent processes.

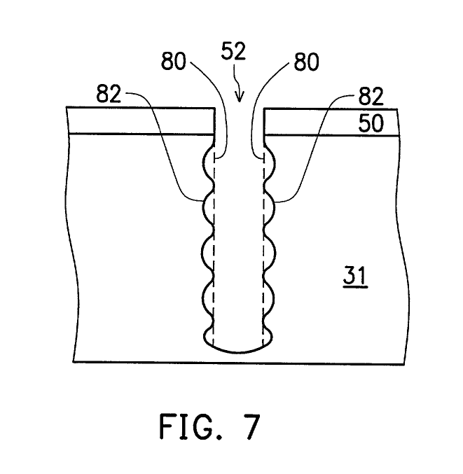

FIG. 6 illustrates the relationship between oxygen flow-rate, [O₂] and process time. FIG. 7 illustrates the profile of a DT according to the oxygen gas flow in FIG. 6. It is well known that, in order to prevent etching stoppages, [O₂] flow, applied to form sidewall polymer to control the shape of the sidewall in a DT, must be reduced, as the DT becomes deeper. The dashed curve 70 represents the variation of [O₂] flow, in FIG. 6 is applied to forming a vertical sidewall as the dashed line 80 shown in FIG. 7, during a trench etching process.

The lower the oxygen flow-rate, the less the polymer covers the sidewall, the more significant the isotropic etching is, and, thus, the more concave the sidewall. Furthermore, the polymer on the sidewall of a DT will not be removed unless it is bombarded by the vertically incoming ions in a plasma chamber, thereby protecting the sidewall formed before. In other words, the shape of the sidewall previously formed during a plasma etching process will not be influenced by the subsequent steps in the plasma etching process. The subsequent steps only affect the profile at the bottom of the DT.

The solid curve 72 in FIG. 6 shows the control of [O₂] according to the present invention. The wavy sidewall 82 in FIG. 7 corresponds to the solid curve 72 in FIG. 6. Since the dashed line 70 in FIG. 6 can introduce a DT with a vertical sidewall, the solid curve 72, which has lower oxygen flow-rates than those shown by the dashed curve 70 during multiple time periods, will induce a wavy sidewall.

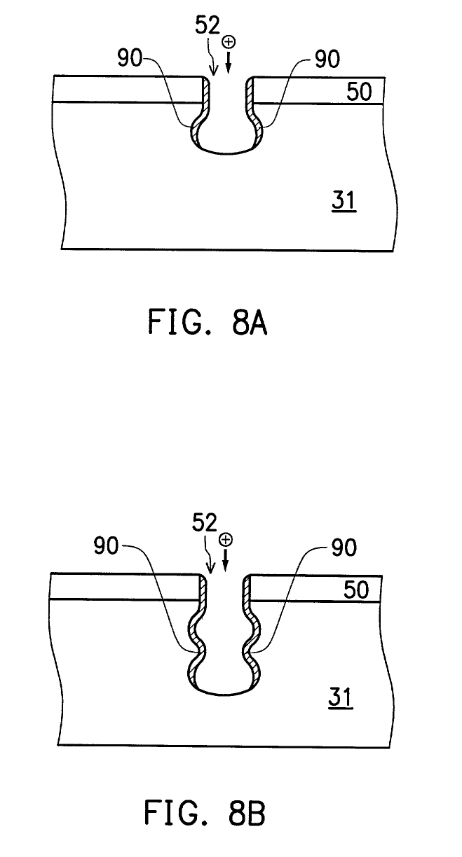

An assumptive cross-section of a DT with an enlarged polymer film at the time T₁ in FIG. 6 is shown in FIG. 8A, where the sidewall is deposited with a polymer film 90. What should be noted is the bottom of the DT where no polymer covers, such that the subsequent plasma process steps only remove the substrate material at the bottom of the DT.

During the period from T₁ to T₂, the [O₂] in curve 72 is less than what is needed to form a vertical sidewall. Thus, isotropic etch dominates during this period to dig a ball-like hole at the bottom of the DT. As time progress, the curve 72 approaches to or crosses the curve 70, and polymer material is deposited to cover the newly-formed hole as expected at the time point T₂ of the curve 70. As a result, it is concluded in FIG. 8B, which shows an assumptive cross-section of the DT of FIG. 8A at the time T₂. Therefore, the wavy sidewall 82 in FIG. 7 can be achieved by the [O₂] control shown by the solid line 72 in FIG. 6.

Please refer to FIG. 5. The present invention performs an an-isotropic etching process to remove a predetermined depth of the substrate 31 under the aperture 52 to form a wavy-shaped deep trench.

Please refer to FIG. 4C again and table 1A. Table 1A is an etch recipe for forming the wavy-shaped deep trench in FIG. 4C. Hereinafter, x-f(n), y and z respectively mean the oxygen flow-rate, the source power and the bias power for generating a vertical sidewall in a DT during the step n. The monotonous function f(n) means the amount of the oxygen flow-rate reduced to preventing etching stop.

TABLE 1A

| Step | | n | n + 1 | n + 2 | n + 3 | n + 4 |
|---|---|---|---|---|---|---|
| Name | | Second | Bye etch | First | Bye etch | Second |
| | | etch | step | etch | step | etch |
| | | step | | step | | step |
| Control- | Oxygen | x − | x − f(n + | x − | x − f(n + | x − |
| ling | flow- | f(n) − | 1) | f(n + 2) + | 3) | f(n + |
| Para- | rate | a % | | a % | | 4) − |
| | | | | | | a % |
| meters | Source | y | y | y | y | Y |
| | power | | | | | |
| | Bias | z | z | z | z | Z |
| | power | | | | | |

| | | | | | |
|---|---|---|---|---|---|
| Note | Second | Transi- | First | Transi- | Second |
| | sidewall | tional | sidewall | tional | sidewall |
| | | sidewall | | sidewall | |

The etch recipe for forming the wavy-shaped trench comprises first etch steps, second etch steps and bye etch steps. The first etch step makes the substrate under etching have a first sidewall 36 with positive slope and deposits a polymer film on the sidewall formed by previous steps for protection. The second etch step vaporizes the polymer film at the bottom of the substrate and makes the substrate under etching have a second sidewall 38 with negative slope. The first and the second etch step are sequentially and periodically performed in the flow of the etch recipe. Each bye etch step is performed between a first etch step and a second step, as shown in Tab.1A, to make the substrate have a transitional sidewall to connect a first sidewall 36 and a second sidewall 38 and round the wavy sidewall.

In today's etch technology, in addition to the oxygen flow rate, the controlling parameters of a plasma etching usually also include other parameters such as the two plasma power sources named as source power and bias power, respectively. Conceptually, the source power provides the power to sustain the plasma density and controls the isotropic etch rate, the bias power provides the bombardment energy of the ions in the plasma and controls the anisotropic etch rate. Any parameter which can control the ratio between isotropic etching rate and un-isotropic etching rate can be utilized and well-controlled according to the present invention to form the expected wavy sidewall. For example, changing, according to the present invention, the variation of the source power for forming a vertical sidewall of a DT can also create a DT with a wavy sidewall. Obviously, two controlling parameters, such as the combination of the source power and the oxygen flow-rate, can be changed at a time to meet the requirement of the slope.

As shown in Tab.1A, suppose the oxygen flow-rate, the source power and the bias power of a bye etch step are used to form the transitional sidewall 42 in FIG. 4C, which is vertical to the top-surface of the substrate 21. According to the method of the present invention and the testing experience, increasing the oxygen flow-rate by 10% with other controlling parameters unchanged will switch the slope of the sidewall during etching from negative to positive. For example, the oxygen flow-rate of the step n+2 is x-f(n+2)+a % to form the first sidewall 36 with positive slope in FIG. 4C; the oxygen rate of the step n+4 is x-f(n+4)−a % to form the second sidewall 38 with negative slope in FIG. 4C. During the first etch steps, thicker passivation (polymer) film will be formed on the surface of the sidewall formed by a preceding etch step. Thus, while performing the second etch step, the surface of the sidewall formed by the preceding etch step will be protected and only the substrate near the bottom-surface will be etched. This is why the first sidewall with positive slope will not be affected by the second etch step. Therefore, the etch recipe in which the first etch step, the second etch step and the bye etch step are performed sequentially and periodically can form the wavy-shaped deep trench. It is understood that besides changing the oxygen flow-rate to form the required slope, other controlling parameters, such as the source power and the bias power, can also be changed to form the required slope.

Please refer to FIG. 4D again and table 1B. Table 1B is an etch recipe for forming the wavy-shaped deep trench in FIG. 4D.

TABLE 1B

| step | n | n + 1 | n + 2 | n + 3 | n + 4 | n + 5 | n + 6 |
|---|---|---|---|---|---|---|---|
| name | Second | First | Second | First | First | Second | Second |
| | etch | bye | by | etch | bye | bye | etch |
| | step | etch | etch | step | etch | etch | step |
| | | step | step | | step | step | |
| Controlling | | | | | | | |
| Parameters | | | | | | | |
| Oxyen | x − f | x − f | x − f | x − f | x − f | x − f | x − f |
| flow-rate | (n) − a% | (n + 1) − | (n + 2) + | (n + 3) + | (n + 4) + | (n + 5) − | (n + 6) − |
| | | a/2% | a/2% | a% | a/2% | a/2% | a% |
| Source | y | y | y | y | y | y | y |
| power | | | | | | | |
| Bias | z | z | z | z | z | z | Z |
| Note | Second | First | Second | First | Second | First | Second |
| | sidewall | transitional | transitional | sidewall | transitional | transitional | sidewall |
| | | sidewall | sidewall | | sidewall | sidewall | |

To make the outermost areas of the wavy sidewall 34 of the wavy-shaped deep trench 30 more rounded, more than one bye etch step, as the first and the second bye etch steps in table 1B, are inserted between a first etch step and a second etch step. For example, the changed amounts of oxygen flow-rates of the first and the second bye etch step are −a/2% and +a/2%, respectively. That is, the first and the second bye etch steps gradually change the oxygen flow-rate to form the first and the second transitional sidewall and make the wavy sidewall 34 more round. If there are more bye etch steps which gradually vary the oxygen flow-rate, the rounding effect for the wavy sidewall will be more significant.

The most significant advantage of the method for forming the wavy-shaped deep trench is cost saving. Only one etch tool, for which the required sequence of the first, the second and bye steps has been defined, is needed to form the wavy-shaped deep trench. This simplifies the process flow and saves cost.

By comparison with the method for forming a deep trench according to the prior art, the present invention finely tunes the etch steps in an etch recipe to form a wavy-shaped deep trench. The present invention, applied in DRAM, enlarges the coupling area since the surface area provided by the wavy sidewall meets the requirements of higher capacitance without deepening the deep trench. Applied in MEMS, the present invention improves the sensitivity of a shock/vibration sensor by enhance the possibility for the rod 45 touching the wavy-side wall 34. Furthermore, the present invention requires only one etching tool to perform etch steps, thus saving costs.

While the invention has been described by way of example and in terms of the preferred embodiment, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A method for forming a wavy-shaped deep trench on a substrate, the method comprising the following steps:
forming a shielding layer with an aperture on the substrate;
performing a first etch step to form in the substrate a first sidewall with positive slope under the aperture;
performing a second etch step to form in the substrate a second sidewall with negative slope under the aperture; and
sequentially and periodically performing the first etch step and the second etch step to remove a predetermined depth of the substrate and form the wavy-shape deep trench.

2. The method of claim 1, wherein the method further comprises a plurality of bye etch steps, each bye etch step being performed between the first etch step and the second etch step to form in the substrate a transitional sidewall under the aperture.

3. The method of claim 2, wherein the transitional sidewall is vertical to the top-surface of the substrate.

4. The method of claim 2, wherein the difference among the first etch step, the second etch step and the bye etch step is the alteration of one of the controlling parameters of source power, bias power and oxygen flow-rate.

5. The method of claim 1, wherein the first etch step and the second etch step both comprise the controlling parameters of source power, bias power and oxygen flow-rate.

6. The method of claim 5 wherein the difference between the first etch step and the second etch step is altering one of the controlling parameters of source power, bias power and oxygen flow-rate.

7. The method of claim 6, wherein the difference among the first etch step, the second etch step and the bye etch step is the alteration of one of the controlling parameters of source power, bias power and oxygen flow-rate.

8. A method for forming a wavy-shaped deep trench on a substrate, the method comprising the following steps:
forming a shielding layer with an aperture on the substrate;
performing an isotropic-dominate etch step to form a concave sidewall under the aperture in the substrate;
forming a passivation film on the concave sidewall to protect the concave sidewall from damage by any subsequent plasma process; and
alternatively excuting the steps of performing the isotropic-dominate etch step and forming a passivation film to remove a predetermined depth of the substrate to form the wavy-shape deep trench.

9. The method as claimed in claim 8 wherein the isotropic-dominate etch step has an oxygen gas flow-rate less than that in a plasma etching step for forming a vertical sidewall under the aperture.

10. The method as claimed in claim 8 wherein the step of forming a passivation film has an oxygen gas flow-rate higher than that in a plasma etching step for forming a vertical sidewall under the aperture.

11. The method of claim 8 wherein the substrate is silicon.

12. The method of claim 8 wherein the shielding layer is photoresist.

13. The method of claim 8 wherein the shielding layer is silicon oxide.
